(19) United States
(12) Patent Application Publication
(10) Pub. No.: US 2026/0223401 A1
(43) Pub. Date: Jul. 30, 2026

(54) STACKED MULTI-GATE DEVICE

(71) Applicant: Taiwan Semiconductor Manufacturing Company, Ltd., Hsin-Chu (TW)

(72) Inventors: Amanda Chen, Hsinchu (TW); Huang-Lin Chao, Hsinchu City (TW); Pinyen Lin, Rochester, NY (US)

(21) Appl. No.: 19/037,239

(22) Filed: Jan. 26, 2025

(51) Int. Cl. H10D 30/67; H10D 30/00; H10D 30/01; H10D 30/43; H10D 62/10; H10D 84/01; H10D 84/85

(52) U.S. Cl. CPC H10D 30/6735; H10D 30/014; H10D 30/0191; H10D 30/43; H10D 30/502; H10D 62/121; H10D 84/0167; H10D 84/017; H10D 84/0188; H10D 84/851

(57) ABSTRACT

Semiconductor devices and methods of forming the same are provided. An exemplary method includes forming a plurality of nanostructures over a substrate, forming a first source/drain feature coupled to a bottommost nanostructure of the plurality of nanostructures, forming a second source/drain feature coupled to a topmost nanostructure of the plurality of nanostructures, forming a first gate structure wrapping around the bottommost nanostructure, and forming a second gate structure wrapping around the topmost nanostructure, where the second gate structure comprises an aluminum-containing n-type work function layer, the first gate structure comprises a first p-type work function layer, a second p-type work function layer, and a diffusion barrier layer disposed between the first p-type work function layer and the second p-type work function layer, wherein an aluminum concentration of the first p-type work function layer is less than an aluminum concentration of the second p-type work function layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FETs) where an n-type multi-gate transistor and a p-type multi-gate transistor are stacked vertically, one over the other. While existing C-FETs are generally adequate, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a perspective view of a semiconductor device including a vertical C-FET, according to one or more aspects of the present disclosure.

FIG. 2 illustrates a flow chart of a method for forming a semiconductor device including a vertical C-FET, according to one or more aspects of the present disclosure.

FIGS. 3, 4, 5, 6, 7, 8, 9, and 12 illustrate fragmentary cross-sectional views of the semiconductor device during various fabrication stages in the method of FIG. 2, according to various aspects of the present disclosure.

FIG. 10 illustrates an enlarged portion of the semiconductor device shown in FIG. 9, according to one or more aspects of the present disclosure.

FIGS. 11A, 11B, 11C depict fragmentary cross-sectional views of alternative configurations of the semiconductor device shown in FIG. 10, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be a complementary field effect transistor (C-FET). The multi-gate devices in a C-FET may be FinFETs or GAA transistors. Gate electrode of a functional gate structure may include one or more work function layers with proper work functions such that the corresponding transistor is enhanced for its device performance. In some cases, the gate electrode of the bottom multi-gate device includes a p-type work function layer, and the gate electrode of the top multi-gate device includes an n-type work function layer. When the n-type work function layer is formed over the p-type work function layer, elements (e.g., aluminum) of the n-type work function layer may diffuse into the p-type work function layer thereunder, disadvantageously affecting the work function position of the p-type work function layer and thus the threshold voltage of the bottom multi-gate device. Thus, it is desirable to find ways to reduce aluminum diffusion without adversely affecting other aspects of the C-FET.

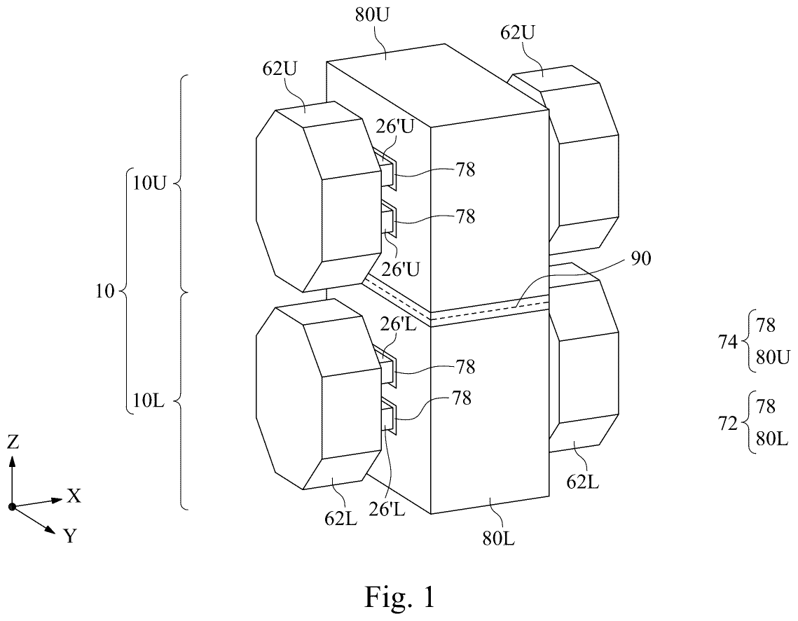

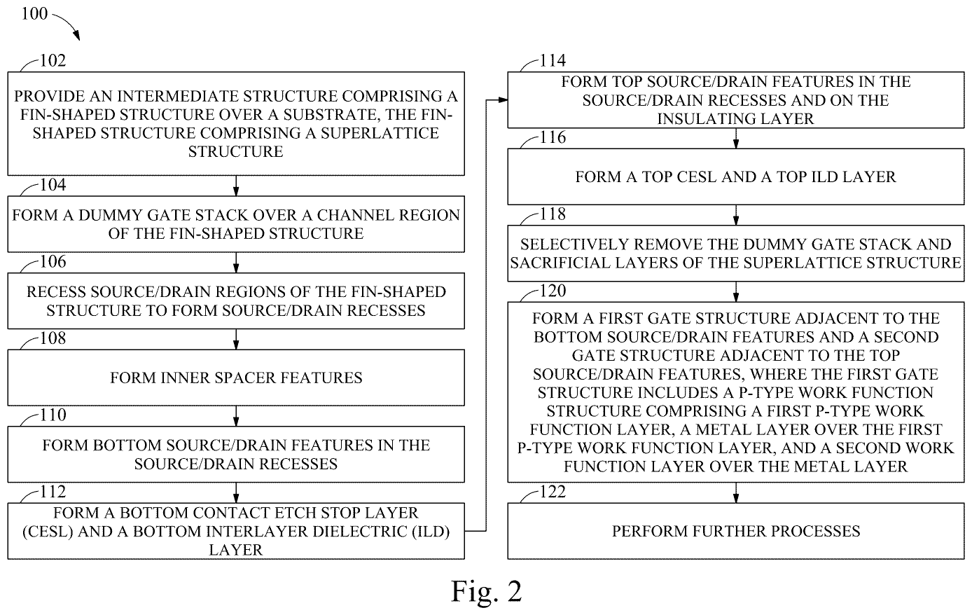

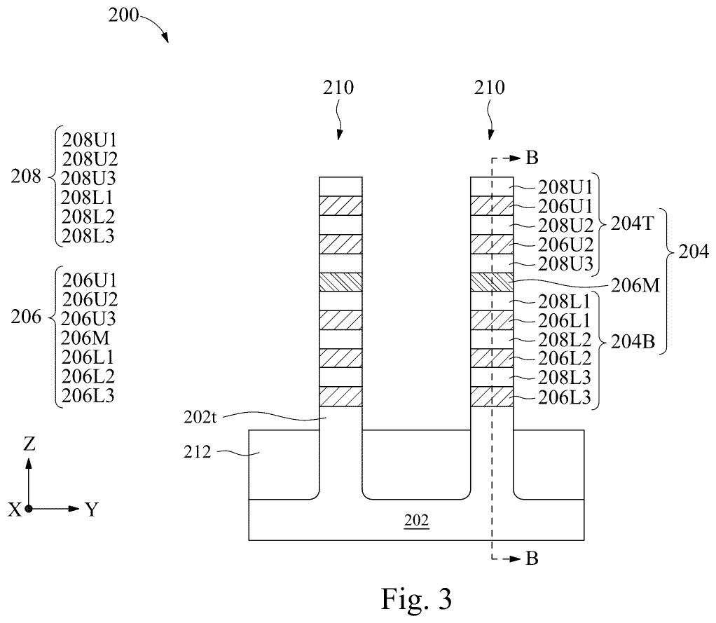

The various aspects of the present disclosure will now be described in more detail with reference to the figures. In that regard, FIG. 1 illustrates a perspective view of a semiconductor device including a vertical C-FET, according to one or more aspects of the present disclosure. FIG. 2 illustrates a flow chart of a method 100 for forming a semiconductor device 200 including a vertical C-FET, according to one or more aspects of the present disclosure. Method 100 is described below in conjunction with FIGS. 3-12, which are fragmentary cross-sectional views of the intermediate structure 200 at different stages of fabrication according to embodiments of method 100. Method 100 is merely an example and is not intended to limit the present disclosure to what is explicitly illustrated therein. Additional steps may be provided before, during and after method 100, and some steps described can be replaced, eliminated, or moved around for additional embodiments of the method. Not all steps are described herein in detail for reasons of simplicity. Because the intermediate structure 200 will be fabricated into a semiconductor device 200 upon conclusion of the fabrication processes, the intermediate structure 200 may be referred to as the semiconductor device 200 as the context requires. Additionally, throughout the present application and across different embodiments, like reference numerals denote like features with similar structures and compositions, unless otherwise excepted. For avoidance of doubts, the X, Y and Z directions in the figures are perpendicular to one another and are used consistently.

FIG. 1 depicts an exemplary semiconductor device (e.g., C-FET) 10. The semiconductor device 10 includes a lower device 10L (e.g., p-type transistor) and an upper device 10U (e.g., n-type transistor) over the lower device 10L. The lower device 10L includes channel layer 26′L wrapped around by a bottom gate structure 72. The bottom gate structure 72 includes a gate dielectric layer 78 and a gate electrode 80L. The lower device 10L also includes source/drain features (e.g., p-type epitaxial source/drain features) 62L coupled to the channel layers 26′L and adjacent the bottom gate structure 72.

The upper device 10U includes channel layer 26′U wrapped around by an upper gate structure 74. The upper gate structure 74 includes the gate dielectric layer 78 and a gate electrode 80U. The upper device 10U also includes source/drain features (e.g., n-type epitaxial source/drain features) 62U coupled to the channel layers 26′U and adjacent the upper gate structure 74. An isolation layer 90 is disposed between the upper device 10U and the lower device 10L to electrically insulate the upper gate structure 74 of the upper device 10U from the bottom gate structure 72 of the lower device 10L. The configurations of the elements in the semiconductor device 10 described above are given for illustrative purposes and can be modified depending on the actual implementations. It is understood that some features are omitted in this figure for reason of simplicity.

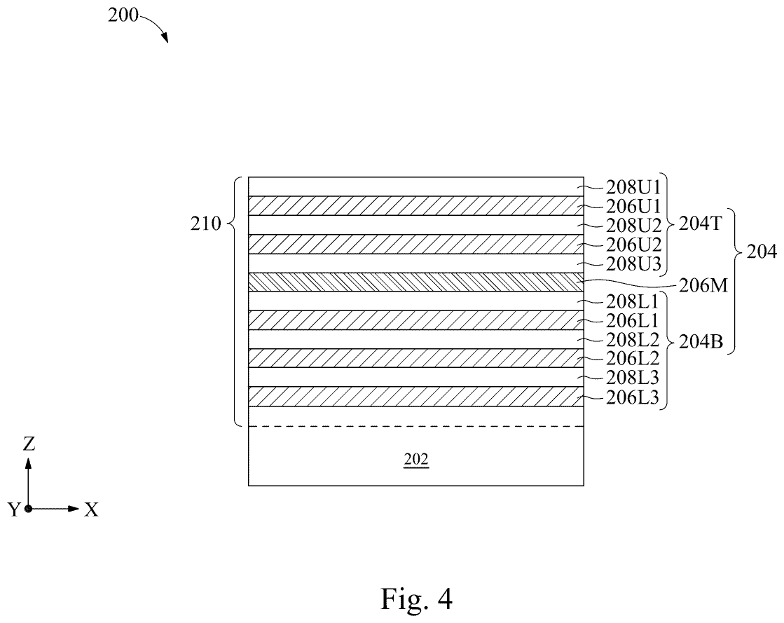

Referring now to FIGS. 2 and 3-4, method 100 includes a block 102 where an intermediate structure 200 is received. FIG. 3 depicts a cross-sectional view of the intermediate structure 200, and FIG. 4 depicts a cross-sectional view of the intermediate structure 200 taken along line B-B shown in FIG. 3. The intermediate structure 200 includes a substrate 202. In one embodiment, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202.

The intermediate structure 200 also includes fin-shaped structures 210 protruding from the substrate 202. In the present embodiments, the fin-shaped structure 210 is formed from a superlattice structure 204 and a portion of the substrate 202. The superlattice structure 204 may be deposited over the substrate 202 using an epitaxy process. Suitable epitaxy processes include vapor-phase epitaxy (VPE), ultra-high vacuum chemical vapor deposition (UHV-CVD), molecular beam epitaxy (MBE), and/or other suitable processes. The superlattice structure 204 includes a number of channel layers 208 interleaved by a number of sacrificial layers 206. The sacrificial layers 206 and the channel layers 208 are deposited alternatingly, one-after-another, to form the superlattice structure 204. The channel layers 208 and the sacrificial layers 206 may have different semiconductor compositions. In some implementations, the channel layers 208 are formed of silicon (Si) and sacrificial layers 206 are formed of silicon germanium (SiGe). In these implementations, the additional germanium content in the sacrificial layers 206 allow selective removal or recess of the sacrificial layers 206 without inducing substantial damages to the channel layers 208.

For ease of references, the superlattice structure 204 may be vertically divided into a bottom portion 204B, a middle sacrificial layer 206M on the bottom portion 204B, and a top portion 204T on the middle sacrificial layer 206M. In this depicted example, the bottom portion 204B of the superlattice structure 204 includes channel layers 208L1, 208L2 and 208L3 interleaved by sacrificial layers 206L1, 206L2, and 206L3. The top portion 204T of the superlattice structure 204 includes channel layers 208U1, 208U2 and 208U3 interleaved by sacrificial layers 206U1 and 206U2. The channel layers 208L1, 208L2, 208L3, 208U1, 208U2, and 208U3 will provide nanostructures for the C-FET. In some embodiments, the channel layers 208U1-208U2 will provide channel members for a top GAA transistor of the C-FET, and the channel layers 208L2-208L3 will provide channel members for a bottom GAA transistor in the C-FET. The term “channel member(s)” is used herein to designate any material portion for channel(s) in a transistor with nanoscale dimensions, and having an elongate shape, regardless of the cross-sectional shape of this portion. A germanium content of the middle sacrificial layer 206M may be different from the germanium content of other sacrificial layers (e.g., sacrificial layers 206U1-206U2, sacrificial layers 206L1-206L3) of the top portion 204T and bottom portion 204B. In some embodiments, a germanium content of the middle sacrificial layer 206M is greater than a germanium content of the other sacrificial layers 206U1-206U2 and 206L1-206L3 such that the entirety of the middle sacrificial layer 206M may be selectively removed during the formation of inner spacer recesses.

It is noted that the superlattice structure 204 in FIGS. 3-4 includes six (6) layers of the channel layers 208 interleaved by six (6) layers of sacrificial layers 206, which is for illustrative purposes only and not intended to be limiting beyond what is specifically recited in the claims. It can be appreciated that any number of the channel layers 208 can be included in the superlattice structure 204 and distributed within the bottom portion 204B and the top portion 204T. The number of layers depends on the desired number of channels members for the top GAA transistor and the bottom GAA transistor. In some embodiments, the number of the channel layers 208 in the superlattice structure 204 may be between 4 and 10. The thicknesses of the channel layers 208 and the sacrificial layers 206 may be selected based on device performance considerations of the bottom GAA transistor, the top GAA transistor, and the C-FET as a whole.

After forming the superlattice structure 204, the superlattice structure 204 and a portion of the substrate 202 are then patterned to form the fin-shaped structures 210. The patterned portion of the substrate 202 may be referred to as a protrusion 202t, a mesa 202t, or a base fin 202t. For patterning purposes, a hard mask layer may be deposited over the superlattice structure 204. The hard mask layer may be a single layer or a multilayer. In one example, the hard mask layer includes a silicon oxide layer and a silicon nitride layer over the silicon oxide layer. As shown in FIGS. 3-4, each fin-shaped structure 210 extends vertically along the Z direction from the substrate 202 and extends lengthwise along the X direction. The fin-shaped structures 210 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the superlattice structure 204 and the substrate 202 to form the fin-shaped structures 210.

The intermediate structure 200 also includes an isolation feature 212 (shown in FIG. 3) formed around the fin-shaped structures 210 to separate two adjacent fin-shaped structures 210. The isolation feature 212 may also be referred to as a shallow trench isolation (STI) feature 212. In an example process, a dielectric material for the isolation feature 212 is deposited over the intermediate structure 200, including the fin-shaped structure 210, using CVD, subatmospheric CVD (SACVD), flowable CVD, spin-on coating, and/or other suitable process. Then, the deposited dielectric material is planarized and recessed to form the isolation feature 212. As shown in FIG. 3, the fin-shaped structure 210 rises above the isolation feature 212. The dielectric material for the isolation feature 212 may include silicon oxide, silicon oxynitride, fluorine-doped silicate glass (FSG), a low-k dielectric, combinations thereof, and/or other suitable materials.

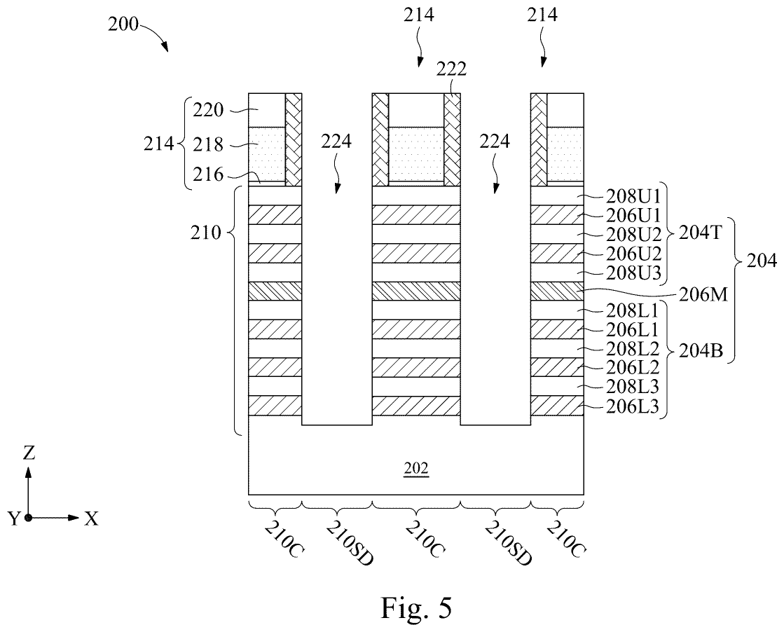

Referring to FIGS. 2 and 5, method 100 includes a block 104 where dummy gate stacks 214 are formed over channel regions 210C of the fin-shaped structure 210. In some embodiments, a gate replacement process (or gate-last process) is adopted where the dummy gate stack 214 serves as a placeholder for a functional gate structure. Other processes and configurations are possible. To form the dummy gate stack 214, a dummy dielectric layer 216, a dummy gate electrode layer 218, and a gate-top hard mask layer 220 are deposited over the intermediate structure 200. The deposition of these layers may include use of chemical vapor deposition (CVD), low-pressure CVD (LPCVD), plasma-enhanced CVD (PECVD), physical vapor deposition (PVD), atomic layer deposition (ALD), thermal oxidation, e-beam evaporation, other suitable deposition techniques, and/or combinations thereof. The dummy dielectric layer 216 may include silicon oxide, the dummy gate electrode layer 218 may include polysilicon, and the gate-top hard mask layer 220 may be a multi-layer structure that includes silicon oxide and silicon nitride. Using photolithography and etching processes, the gate-top hard mask layer 220 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching, wet etching, and/or other etching methods. Like the fin-shaped structures 210, the dummy gate stack 214 may also be patterned using double-patterning or multiple-patterning techniques. Thereafter, using the patterned gate-top hard mask 220 as an etch mask, the dummy dielectric layer 216 and the dummy gate electrode layer 218 are then etched to form the dummy gate stack 214. The dummy gate stack 214 extends lengthwise along the Y direction to wrap over the fin-shaped structure 210 and lands on the isolation feature 212. The portion of the fin-shaped structure 210 underlying the dummy gate stack 214 defines a channel region 210C. The channel region 210C and the dummy gate stack 214 also define source/drain regions 210SD that are not vertically overlapped by the dummy gate stack 214. The channel region 210C is disposed between two source/drain regions 210SD along the Y direction. Source/drain region(s) may refer to a source region for forming a source and/or a drain region for forming a drain, individually or collectively dependent upon the context.

Still referring to FIGS. 2 and 5, method 100 includes a block 106 where source/drain regions 210SD of the fin-shaped structure 210 are recessed to form source/drain recesses 224. Operations at block 106 may include formation of at least one gate spacer 222 over the sidewalls of the dummy gate stack 214 before the source/drain regions 210SD are recessed. In some embodiments, the formation of the at least one gate spacer 222 includes deposition of one or more dielectric layers over the intermediate structure 200. In an example process, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. After the formation of the gate spacer 222, an anisotropic etch process is performed to the intermediate structure 200 to form the source/drain recesses 224. The etch process at block 106 may be a dry etch process or other suitable etch process. An example dry etch process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As shown in FIG. 5, sidewalls of the sacrificial layers 206 and the channel layers 208 in the channel regions 210C are exposed in the source/drain recesses 224.

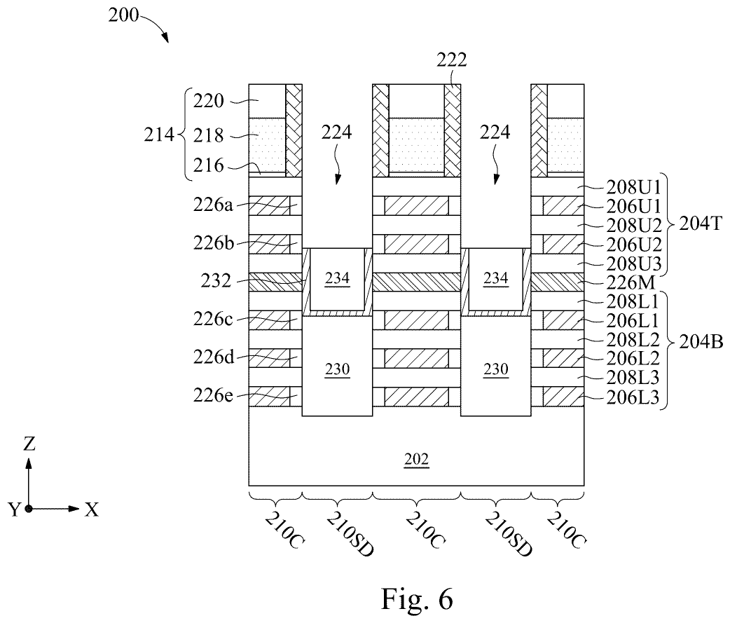

Referring to FIGS. 2 and 6, method 100 includes a block 108 where inner spacer features 226 are formed. At block 108, the sacrificial layers 206 exposed in the source/drain recesses 224 are selectively and partially recessed to form inner spacer recesses, while the exposed channel layers 208 are substantially unetched. The middle sacrificial layer 206M, due to its greater germanium content, may be substantially removed during the formation of inner spacer recesses. In some embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include use of hydrogen fluoride (HF) or ammonium hydroxide (NH₄OH).

After the formation of the inner spacer recesses, an inner spacer material layer is deposited over the intermediate structure 200, including in the inner spacer recesses. Additionally, as shown in FIG. 6, the inner spacer material layer may also be deposited in the space left behind by selective removal of the middle sacrificial layer 206M. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess portions of the inner spacer material layer over the dummy gate stack 214, the gate spacer 222, and sidewalls of the channel layers 208, thereby forming the inner spacer features 226 and the middle dielectric layer 226M as shown in FIG. 6. In the present embodiments, the inner spacer features 226 includes inner spacer features 226a and 226b disposed over the middle dielectric layer 226M and inner spacer features 226c, 226d, and 226e disposed under the middle dielectric layer 226M. Each of the inner spacer features 226a-226e and the middle dielectric layer 226M is disposed between two vertically adjacent channel layers 208. In some embodiments, the etch back process at block 108 may be a dry etch process that includes use of an oxygen-containing gas, hydrogen, nitrogen, a fluorine-containing gas (e.g., NF₃, CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof.

Still referring to FIGS. 2 and 6, method 100 includes a block 110 where bottom source/drain features 230 are formed in the source/drain recesses 224. In some embodiments, before the deposition of the bottom source/drain features 230, a blocking layer (not shown) may be deposited over the intermediate structure 200 to cover sidewalls of the top portion 204T of the superlattice structure 204. The blocking layer may also cover sidewalls of the middle dielectric layer 226M and the channel layer 208L1. The blocking layer may include dielectric materials. After the formation of the blocking layer, the bottom source/drain features 230 may be formed using an epitaxial process, such as VPE, UHV-CVD, MBE, and/or other suitable processes. The epitaxial growth process may use gaseous and/or liquid precursors, which interact with the composition of the substrate 202 as well as the channel layers 208 not covered by the blocking layer. In the present embodiments, the epitaxial growth of bottom source/drain features 230 may take place from both the top surface of the substrate 202 and the exposed sidewalls of the bottom channel layers 208L2 and 208L3. The blocking layer, due to its dielectric composition, blocks formation of the bottom source/drain features 230 on sidewalls of the channel layers 208U1-208U3 and 208L1. As illustrated in FIG. 6, the bottom source/drain features 230 are in physical contact with (or adjoining) the channel layers 208L2 and 208L3. Depending on the design, the bottom source/drain features 230 may be n-type or p-type. In the depicted embodiments, the bottom source/drain features 230 are p-type source/drain features and may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process.

Still referring to FIGS. 2 and 6, method 100 includes a block 112 where a bottom contact etch stop layer (CESL) 232 and a bottom interlayer dielectric (ILD) layer 234 are formed over the bottom source/drain features 230. The bottom CESL 232 may include silicon nitride, silicon oxynitride, and/or other materials and may be formed by CVD, ALD, plasma-enhanced chemical vapor deposition (PECVD) process and/or other suitable deposition or oxidation processes. In an embodiment, the bottom CESL 232 includes silicon nitride, and a ratio of nitrogen concentration to silicon concentration (i.e., N/Si) of the bottom CESL 232 is in a range between about 1.1 and about 1.3. In some embodiments, the bottom CESL 232 is first conformally deposited on the intermediate structure 200 and the bottom ILD layer 234 is deposited over the bottom CESL 232 by spin-on coating, flowable CVD (FCVD), CVD, or other suitable deposition technique. The bottom ILD layer 234 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The bottom CESL 232 and the bottom ILD layer 234 may be etched back to exposed sidewalls of the channel layers 208U1 and 208U2. In embodiments presented by FIG. 6, after being etched back, the bottom CESL 232 is in direct contact with the inner spacer features 226b-226c, the channel layers 208U3, 208L1, and the middle dielectric layer 226M. The blocking layer may be removed during the etch back of the bottom CESL 232 and the bottom ILD layer 234.

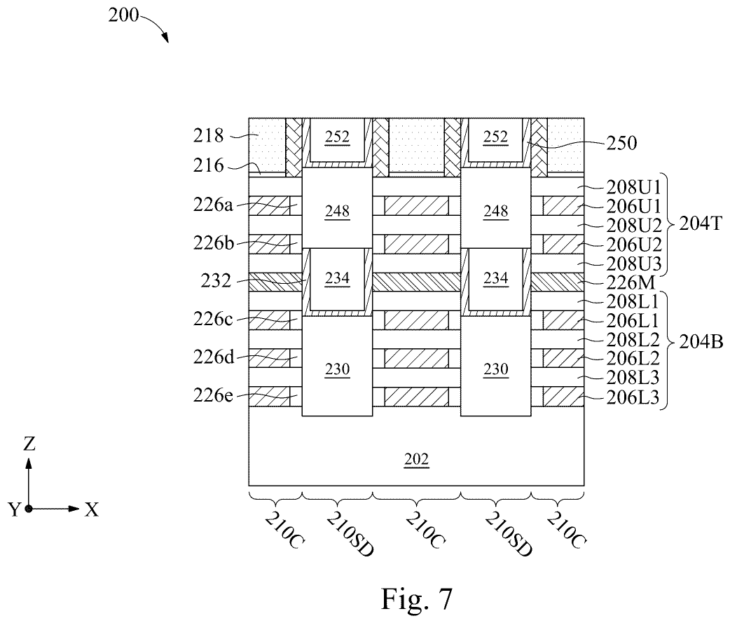

Referring to FIGS. 2 and 7, method 100 includes a block 114 where top source/drain features 248 are formed over the bottom CESL 232 and the bottom ILD layer 234. The top source/drain features 248 may be formed using an epitaxial process, such as VPE, UHV-CVD, MBE, and/or other suitable processes. The epitaxial growth process may use gaseous and/or liquid precursors, which interact with composition of the channel layers (e.g., channel layers 208U1 and 208U2) of the top portion 204T of the superlattice structure 204. The epitaxial growth of top source/drain features 248 may take place from the exposed sidewalls of the top channel layers 208U1 and 208U2. The deposited top source/drain features 248 are in physical contact with (or adjoining) the channel layers of the top portion 204T of the superlattice structure 204. Depending on the design, the top source/drain features 248 may be n-type or p-type. In the depicted embodiments, the top source/drain features 248 are n-type source/drain features and may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process.

Still referring to FIGS. 2 and 7, method 100 includes a block 116 where a top CESL 250 and a top ILD layer 252 are deposited over the top source/drain features 248. The top CESL 250 may include silicon nitride, silicon oxynitride, and/or other materials known in the art and may be formed by CVD, ALD, plasma-enhanced chemical vapor deposition (PECVD) process and/or other suitable deposition or oxidation processes. In some embodiments, the top CESL 250 is first conformally deposited on the intermediate structure 200 and the top ILD layer 252 is then deposited over the top CESL 250 by spin-on coating, FCVD, CVD, or other suitable deposition technique. The top ILD layer 252 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the top ILD layer 252, the intermediate structure 200 may be annealed to improve integrity of the top ILD layer 252. To remove excess materials and to expose top surfaces of the dummy gate electrode layers 218, a planarization process, such a chemical mechanical polishing (CMP) process may be performed.

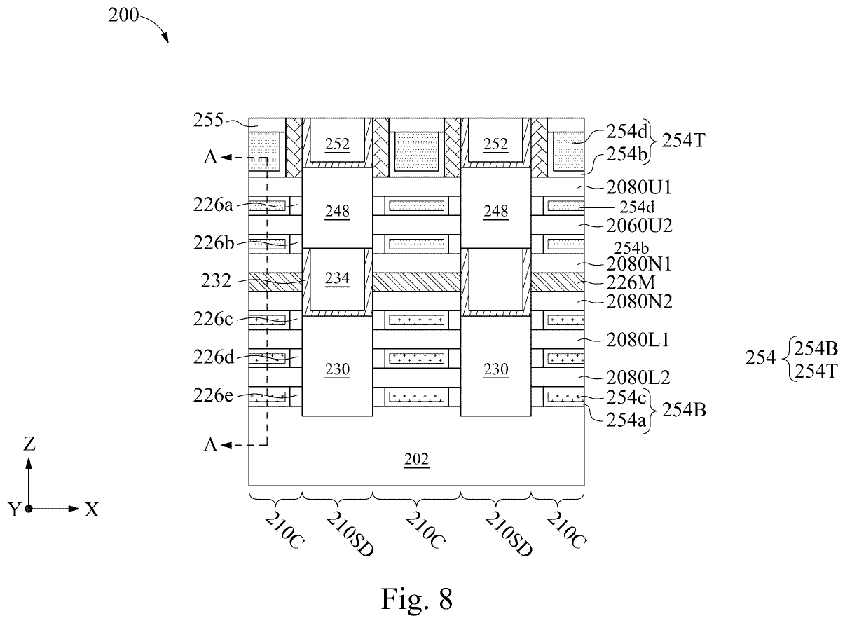

Referring to FIGS. 2 and 8, method 100 includes a block 118 where the dummy gate stack 214 and the sacrificial layers 206 are selectively removed. Operations at block 118 may include removal of the dummy gate stacks 214, release of the channel layers 208 as channel members (including top channel members 2080U1, 2080U2, and bottom channel members 2080L1, and 2080L2) and nanostructures (including the nanostructures 2080N1 and 2080N2). The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. After the removal of the dummy gate stacks 214, sidewalls of the channel layers 208 and sacrificial layers 206 in the channel regions 210C are exposed. Thereafter, the sacrificial layers 206 in the channel regions 210C are selectively removed to release the channel layers 208 as the channel members (including the top channel members 2080U1, 2080U2, the bottom channel members 2080L1, and 2080L2) and nanostructures (including the nanostructures 2080N1 and 2080N2). The selective removal of the sacrificial layers 206 may be implemented by a selective dry etch, a selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH. In embodiments represented by FIG. 8, the top channel members 2080U1 and 2080U2 are in direct contact with the top source/drain features 248; the bottom channel members 2080L1 and 2080L2 are in direct contact with the bottom source/drain features 230; and the nanostructures 2080N1, 2080N2 and the middle dielectric layer 226M are in direct contact with the bottom CESL 232.

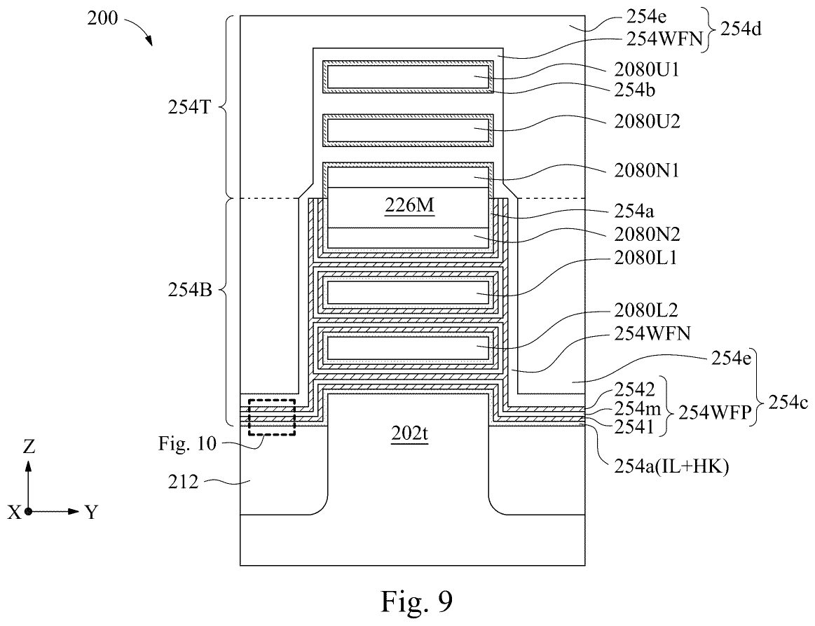

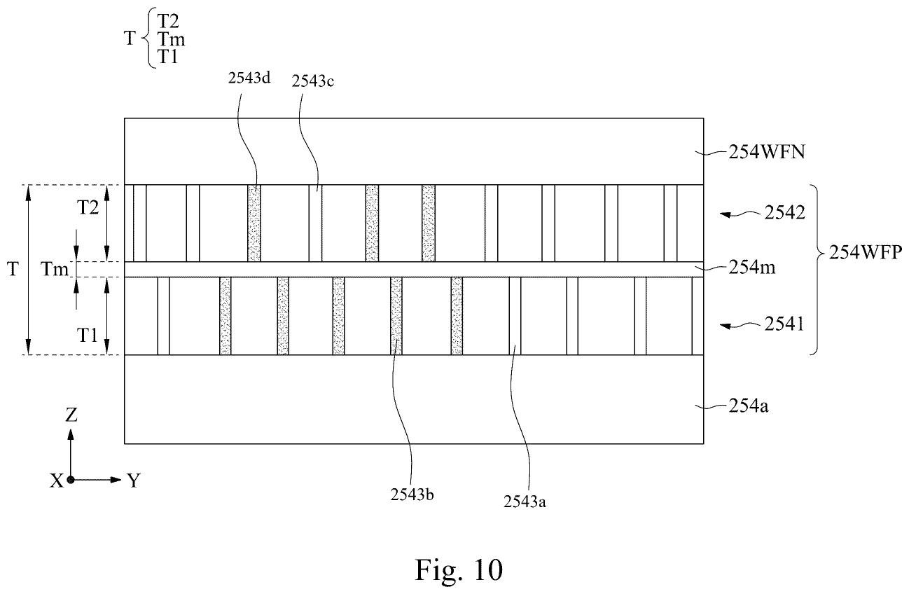

Referring to FIGS. 2 and 8-10, method 100 includes a block 120 where a bottom gate structure 254B is formed adjacent to the bottom source/drain features 230 and a top gate structure 254T is formed adjacent to the top source/drain features 248. The bottom gate structure 254B and the top gate structure 254T may be individually or collectively referred to as a gate structure 254. FIG. 9 depicts a cross-sectional view of the intermediate structure 200 taken along line A-A as shown in FIG. 8. FIG. 10 depicts an enlarged portion of the gate structure 254 shown in FIG. 9.

After the selective removal of the sacrificial layers 206, the bottom gate structure 254B is formed to wrap around each of the bottom channel members 2080L1 and 2080L2, thereby forming a bottom multi-gate transistor (e.g., 10L in FIG. 1), and the top gate structure 254T is formed to wrap around each of the top channel members 2080U1 and 2080U2, thereby forming a top multi-gate transistor (e.g., 10U in FIG. 1) disposed over the bottom multi-gate transistor. In the depicted embodiments, both the bottom multi-gate transistor and the top multi-gate transistor are GAA transistors. In the cross-sectional view represented by FIG. 8, the bottom gate structure 254B and the top gate structure 254T are physically isolated from each other by the middle dielectric layer 226M, and in the cross-sectional view represented by FIG. 9, the top gate structure 254T is formed over the bottom gate structure 254B.

The formation of the bottom gate structure 254B and top gate structure 254T includes forming a bottom gate dielectric layer 254a surrounding the channel members 2080L1 and 2080L2 and a top gate dielectric layer 254b surrounding the channel members 2080U1 and 2080U2. In an embodiment, the bottom gate dielectric layer 254a and the top gate dielectric layer 254b are formed simultaneously and have a same composition. For example, each of the bottom gate dielectric layer 254a and the top gate dielectric layer 254b includes an interfacial layer (not separately labeled) and a high-K dielectric layer (not separately labeled) over the interfacial layer. The interfacial layer may be formed over the channel members 2080U1-2080U2, 2080L1-2080L2, and the nanostructures 2080N1-2080N2, and cover top and sidewall surfaces of protrusions 202t. The interfacial layer may be formed by thermal oxidation, chemical oxidation, atomic layer deposition (ALD), chemical vapor deposition (CVD), other suitable process, or a combination thereof. For embodiments in which the interfacial layer is formed by thermal oxidation, the interfacial layer forms on semiconductor surfaces (e.g., channel members 2080U1-2080U2, 2080L1-2080L2, and the nanostructures 2080N1-2080N2), but not dielectric surfaces (e.g., isolation features 212). In some other embodiments, the interfacial layer may be conformally deposited over the substrate 202, including on the isolation features 212. The interfacial layer includes a dielectric material, such as SiO₂, SiGeOx, HfSiO, SiON, other dielectric material, or a combination thereof. In some embodiments, the interfacial layer is group IV-based oxide layers, which generally refer to oxides of a group IV-based material (i.e., a material that includes at least one group IV element, such as Si, Ge, C, etc.). In some embodiments, the interfacial layer is group III-V-based oxide layers, which generally refer to oxides of a group III-V-based material (i.e., a material that includes at least one group III element, such as Al, Ga, In, B, etc., and at least one group V element, such as N, P, As, Sb, etc.). The high-K dielectric layer may include dielectric materials having a high dielectric constant, for example, greater than a dielectric constant of silicon oxide. Exemplary high-K dielectric materials include hafnium, zirconium, tantalum, titanium, oxygen, nitrogen, other suitable constituent, or combinations thereof. In some implementations, the high-K dielectric layer may include a high-K dielectric material including, for example, HfO₂, HfSiO, HfSiON, HfTaO, HfTiO, HfZrO, ZrO₂, TiO₂, Ta₂O₅, other suitable high-K dielectric material, or combinations thereof.

The formation of the bottom gate structure 254B and top gate structure 254T also includes forming a bottom gate electrode 254c for the bottom gate structure 254B and a top gate electrode 254d for the top gate structure 254T. Each of the bottom and top gate electrodes 254c-254d may include one or more work function layers with proper work functions such that the corresponding transistor is enhanced for its device performance (for example, reduced threshold voltage). For embodiments in which the bottom multi-gate transistor is a p-type transistor and the top multi-gate transistor is an n-type transistor, the bottom gate electrode 254c includes a p-type work function structure 254WFP, and the top gate electrode 254d includes an n-type work function structure 254WFN.

In some existing technologies, an n-type work function layer of the n-type work function structure 254WFN is formed over an p-type work function layer, some elements (e.g., aluminum) may diffuse from the n-type work function layer to the p-type work function layer, affecting a work function position of the p-type work function layer and thus a threshold voltage of the bottom multi-gate transistor. In the present embodiment, besides p-type work function layers, the p-type work function structure 254WFP also includes at least one diffusion barrier layer (e.g., diffusion barrier layer 254m) configured to reduce interdiffusion. In an exemplary process, after forming the gate dielectric layers 254a and 254b, the p-type work function structure 254WFP is formed over the gate dielectric layers 254a-254b and then etched back to expose the gate dielectric layer 254b. The n-type work function structure 254WFN is then formed over the p-type work function structure 254WFP and the gate dielectric layer 254b. Each of the bottom and top gate electrodes 254c-254d may include a metal fill 254e over the n-type work function structure 254WFN and the p-type work function structure 254WFP to reduce contact resistance. In some instance, the metal fill 254e includes tungsten (W). The gate structure 254 may also include a liner layer, a wetting layer, an adhesion layer, a metal alloy or a metal silicide.

Details of the p-type work function structure 254WFP and n-type work function structure 254WFN are described with reference to FIG. 9 and FIG. 10, where FIG. 10 depicts an enlarged portion of the gate structure 254 shown in FIG. 9. The n-type work function structure 254WFN may include a single layer or alternatively a multi-layer structure, such as various combinations of a metal layer with a selected work function to enhance the device performance. By way of example, the n-type work function structure 254WFN may include an n-type work function material, which generally refers to an electrically conductive material tuned to have an n-type work function. In some embodiments, the n-type work function structure 254WFN may include titanium aluminum, titanium aluminum carbide, tantalum carbide, tantalum carbide nitride, tantalum silicon nitride, or a combination thereof. In this illustrated embodiment, the n-type work function structure 254WFN is a single-layer structure and may include an aluminum-containing material, such as TiAl or TiAlC.

To provide satisfactory adhesion between the p-type work function structure 254WFP and its surrounding layers (e.g., the high-K dielectric layer and the n-type work function structure 254WFN), the p-type work function structure 254WFP is formed of a titanium nitride (TiN)-based work function layer. However, titanium nitride has a columnar grain structure with both intercolumnar voids and intracolumnar voids, and aluminum in the n-type work function structure 254WFN may diffuse into the titanium nitride (TiN)-based work function layer through grain boundaries of the titanium nitride (TiN)-based work function layer, resulting in degradation of the titanium nitride (TiN)-based work function layer and unwanted threshold voltage variation of the bottom metal-gate transistor. To reduce aluminum diffusion, in this illustrated embodiment, the p-type work function structure 254WFP includes a first p-type work function layer 2541 on the gate dielectric layer 254a, a second p-type work function layer 2542 under the n-type work function structure 254WFN, and a diffusion barrier layer 254m disposed between the first p-type work function layer 2541 and the second p-type work function layer 2542. Each of the first p-type work function layer 2541 and a second p-type work function layer 2542 may be conformally deposited over the gate dielectric layer 254a by ALD, CVD, or other suitable processes. In an embodiment, to provide satisfactory film adhesion, the first p-type work function layer 2541 includes titanium nitride formed by ALD and is in direct contact with the high-K dielectric layer of the gate dielectric layer 254a, and the second p-type work function layer 2542 includes titanium nitride formed by ALD and is in direct contact with the n-type work function structure 254WFN. However, as stated above, an ALD formed titanium nitride layer also has a columnar grain structure with both intercolumnar voids and intracolumnar voids. If left untreated, a large amount of aluminum in the n-type work function structure 254WFN may diffuse into the first p-type work function layer 2541 and the second p-type work function layer 2542 through grain boundaries of the titanium nitride (TiN). In this present embodiment, the diffusion barrier layer 254m is formed between the first p-type work function layer 2541 and the second p-type work function layer 2542 by, for example, an ALD process. The intercolumnar voids and intracolumnar voids may be at least partially filled by the diffusion barrier layer 254m, and thus diffusion paths in columnar titanium nitride (TiN) grains are decreased or even destroyed. That is, the amount of aluminum that may diffuse into the first p-type work function layer 2541 may be reduced. In other words, aluminum concentration of the first p-type work function layer 2541 is less than aluminum concentration of the second p-type work function layer 2542. Feature 2543a represents diffusion paths in the first p-type work function layer 2541 that have not been fully filled by the diffusion barrier layer 254m, and feature 2543b represents diffusion paths in the first p-type work function layer that have been fully filled by the diffusion barrier layer 254m. Feature 2543c represents diffusion paths in the second p-type work function layer 2542 that have not been fully filled by the aluminum of the n-type work function structure 254WFN, and feature 2543d represents diffusion paths in the second p-type work function layer 2542 that are fully filled by the aluminum of the n-type work function structure 254WFN. In some embodiments, aluminum may diffuse into the diffusion barrier layer 254m and diffuse into the first p-type work function layer 2541. Due to the aluminum diffusion, the diffusion barrier layer 254m may become an aluminum-containing titanium layer, the first p-type work function layer 2541 and the second p-type work function layer 2542 may include aluminum-containing titanium nitride layers with the aluminum concentration relationship described above.

In an embodiment represented by FIG. 9, a lower portion of the n-type work function structure 254WFN is separated from the diffusion barrier layer 254m by the second p-type work function layer 2542, and an upper portion of the n-type work function structure 254WFN is formed on and in direct contact with the diffusion barrier layer 254m, the first p-type work function layer 2541, and the second p-type work function layer 2542. The interface between the n-type work function structure 254WFN and the diffusion barrier layer 254m is below a top surface of the middle dielectric layer 226M and above a bottom surface of the middle dielectric layer 226M.

In this illustrated embodiment, the deposition processes for forming the first p-type work function layer 2541, the second p-type work function layer 2542, and the diffusion barrier layer 254m are performed in-situ. For example, after forming the high-K dielectric layer, the intermediate structure 200 is loaded into a process chamber, where the process chamber is prepared for the ALD processes to form the p-type work function structure 254WMP. During the performing of the ALD processes, the intermediate structure 200 stays in the same process chamber upon completion of the formation of the p-type work function structure 254WMP.

The first p-type work function layer 2541 has a thickness T1, the second p-type work function layer 2542 has a thickness T2, and the diffusion barrier layer 254m has a thickness Tm. To provide enough barrier without substantially affecting the work function position of the first p-type work function layer 2541 and the second p-type work function layer 2542, a ratio of the thickness Tm to a total thickness (i.e., T1+T2) of the first p-type work function layer 2541 and the second p-type work function layer 2542 is in a range between about 0.1 and about 0.2. If the ratio is less than 0.1, the diffusion barrier layer 254m may be too thin to reduce or block diffusion paths in columnar titanium nitride (TiN) grains; and if the ratio is greater than 0.2, the diffusion barrier layer 254m may consume too much sheet-sheet spacing (e.g., the spacing between the channel members 2080L1 and 2080L2) for forming the bottom gate electrode. To keep enough room for forming n-type work function layer 254WFN, a total thickness of the first p-type work function layer 2541 and the second p-type work function layer 2542 may decrease, which may disadvantageously affect the threshold voltage and device performance of the bottom multi-gate transistor. In an embodiment, the thickness T1 is equal to the thickness T2, and a ratio of an aluminum concentration of the second p-type work function layer 2542 to an aluminum concentration of the first p-type work function layer 2541 is greater than 1. In another embodiment, the thickness T2 is less than the thickness T1, and thus, the first p-type work function layer 2541 may play a more important role on an overall work function of the p-type work function structure 254WMP and the threshold voltage. Most of the aluminum that diffused from the n-type work function structure 254WFN may be trapped in the second p-type work function layer 2542 and the diffusion barrier layer 254m. Without changing a total thickness of the p-type work function structure 254WMP, by increasing the thickness T1 and decreasing the thickness T2 (e.g., T2/T1<1), the performance of the bottom multi-gate transistor may be further improved. For example, an improved threshold voltage and enhanced device performance may be achieved due to the reduced aluminum diffusion effect on the first p-type work function layer. In this another embodiment, a ratio of an aluminum concentration of the second p-type work function layer 2542 to an aluminum concentration of the first p-type work function layer 2541 may be greater than 1.5. In an embodiment, the total thickness (i.e., T1+T2) of the first p-type work function layer 2541 and the second p-type work function layer 2542 is between about 1 nm and about 3 nm, and a thickness of the diffusion barrier layer 254m may be between about 0.1 nm and 0.3 nm.

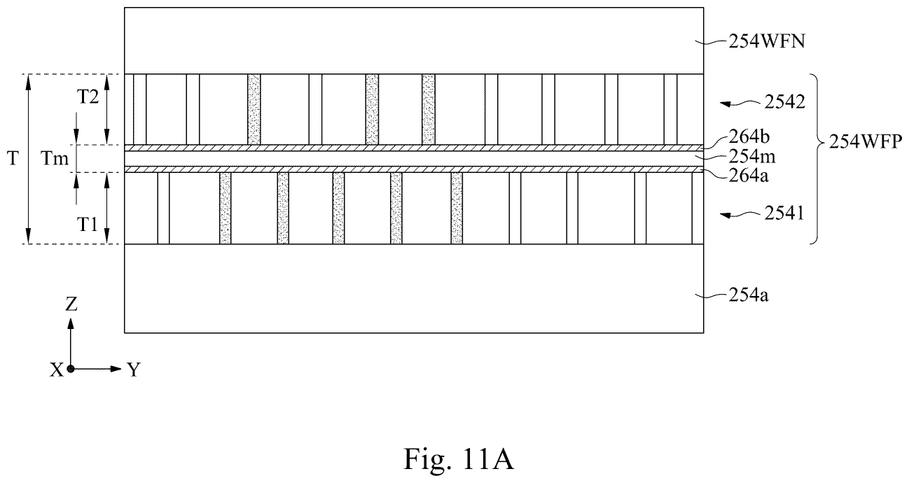

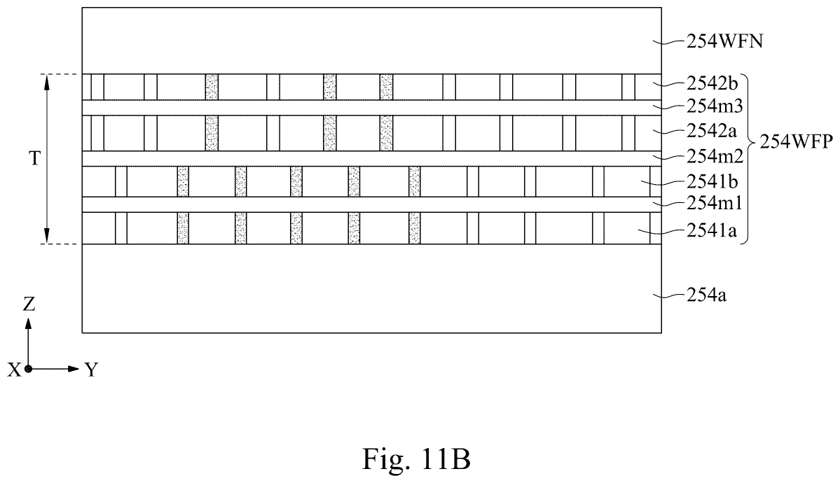

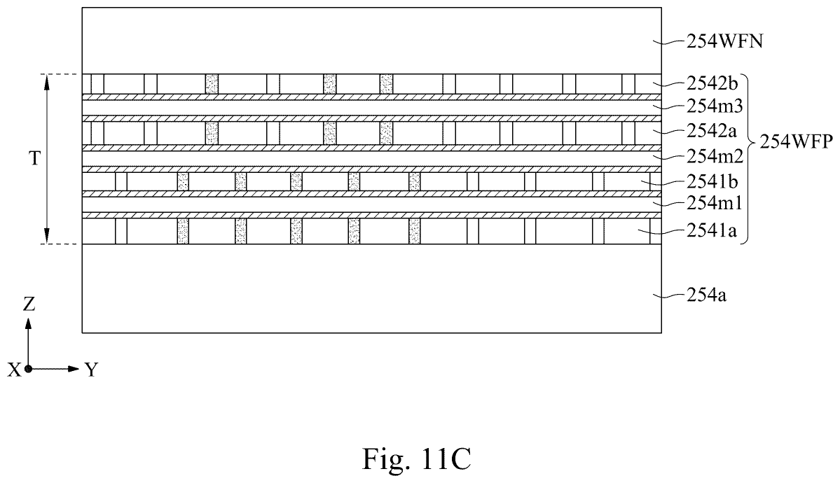

In the above embodiment described with reference to FIG. 10, deposition processes for forming the first p-type work function layer 2541, the diffusion barrier layer 254m, and the second p-type work function layer 2542 are performed in-situ. In another embodiment represented by FIG. 11A, the deposition processes for forming the first p-type work function layer 2541, the diffusion barrier layer 254m, and the second p-type work function layer 2542 are performed ex-situ. In an exemplary process, after forming the gate dielectric layers 254a-254b, the intermediate structure 200 is loaded into a first process chamber, where the first process chamber is prepared for a first ALD process for forming the first p-type work function layer 2541. After performing the first ALD process, the intermediate structure 200, which now includes the first p-type work function layer 2541, is transferred to a second process chamber, where the second process chamber is prepared for a second ALD process for forming the diffusion barrier layer 254m. During the transfer process between the first process chamber and the second process chamber, a top surface of the first p-type work function layer 2541 may be partially oxidized, leading to a first oxide-containing layer 264a. The oxide-containing layer 264a may be an oxide-containing titanium nitride layer (e.g., TiON). After finishing the second ALD process, the intermediate structure 200, which now includes the diffusion barrier layer 254m, is transferred to a third process chamber, where the third process chamber is prepared for a third ALD process for forming the second p-type work function layer 2542. During the transfer process between the second process chamber and the third process chamber, a top surface of the diffusion barrier layer 254m may be partially oxidized, leading to a second oxide-containing layer 264b. The second oxide-containing layer 264b may be an oxide-containing titanium layer (e.g., TiO). Forming the first oxide-containing layer 264a and the second oxide-containing layer 264b increases oxygen concentration in the p-type work function structure 254WFP. Introducing oxygen into the p-type work function structure 254WFP can further reduce aluminum from being diffused from the aluminum-containing n-type work function layer of the n-type work function structure 254WFN into the first p-type work function layer 2541. In some cases, aluminum from the aluminum-containing n-type work function layer of the n-type work function structure 254WFN may diffuse into the second p-type work function layer 2542, the second oxide-containing layer 264b, the diffusion barrier layer 254m, the first oxide-containing layer 264a, and the first p-type work function layer 2541, and aluminum concentrations of those layers may decrease from top to bottom. That is, the first p-type work function layer 2541 may have a lowest aluminum concentration among those layers, and the second p-type work function layer 2542 may have a highest aluminum concentration among those layers. In an embodiment, an aluminum concentration of the second oxide-containing layer 264b is higher than an aluminum concentration of the first oxide-containing layer 264a.

In the above embodiment described with reference to FIG. 10, the p-type work function structure 254WFP includes one diffusion barrier layer 254m disposed between two p-type work function layers (e.g., 2541 and 2542). In another embodiment represented by FIG. 11B, the p-type work function structure 254WFP may include multiple metal barrier layers (e.g., 254m1, 254m2, 254m3). The first and second p-type work function layers 2541 and 2542 are interleaved by those metal barrier layers 254m1-254m3. For example, the first p-type work function layer 2541 is divided into two parts 2541a and 2541b by the diffusion barrier layer 254m1, the second p-type work function layer 2542 is divided into two parts 2542a and 2542b by the diffusion barrier layer 254m3, and the part 2541b and the part 2542a are separated by the diffusion barrier layer 254m2. It is noted that, a total thickness T of the p-type work function structure 254WFP remains unchanged. In an embodiment, a total thickness of different parts of the first p-type work function layer 2541 is T1, a total thickness of different parts of the second p-type work function layer 2542 is T2, and a total thickness of the multiple metal barrier layers 254m1, 254m2, 254m3 is Tm. Although three metal barrier layers (e.g., 254m1, 254m2, 254m3) are illustrated in FIG. 11B, it is understood that the p-type work function structure 254WFP may include any suitable numbers of metal barrier layers.

In another embodiment, as described above with reference to FIG. 11A, the deposition processes for forming different layers in the p-type work function structure 254WFP may be performed ex-situ. This concept can also be applied to the forming the p-type work function structure 254WFP described above with reference to FIG. 11B. Upon completion of the deposition processes, as illustrated by FIG. 11C, each of the metal barrier layers 254m1, 254m2, 254m3 is sandwiched by a top oxide-containing layer and a bottom oxide-containing layer. The bottom oxide-containing layer may be similar to the oxide-containing layer 264a, except that it has a smaller thickness than the oxide-containing layer 264a. The top oxide-containing layer may be similar to the oxide-containing layer 264b, except that it has a smaller thickness than the oxide-containing layer 264b. Aluminum concentrations of the layers in the p-type work function structure 254WFP may decrease from top to bottom.

In the above embodiments, the first and second p-type work function layers 2541 and 2542 include titanium nitride (TiN). Besides titanium nitride (TiN), p-type work function materials also include tantalum nitride (TaN), ruthenium (Ru), molybdenum (Mo), tungsten nitride (WN), zirconium silicide (ZrSi₂), molybdenum silicide (MoSi₂), tantalum silicide (TaSi₂), nickel silicide (NiSi₂), or other p-type work function material. Concept of the present disclosure is also applicable to other p-type work function materials that have columnar grains. Also, in some embodiments, the diffusion barrier layer 254m may include other materials that are able to disrupt the columnar growth of p-type work function layers to reduce aluminum diffusion. For example, the diffusion barrier layer 254m may include tungsten nitride, molybdenum nitride, tantalum nitride.

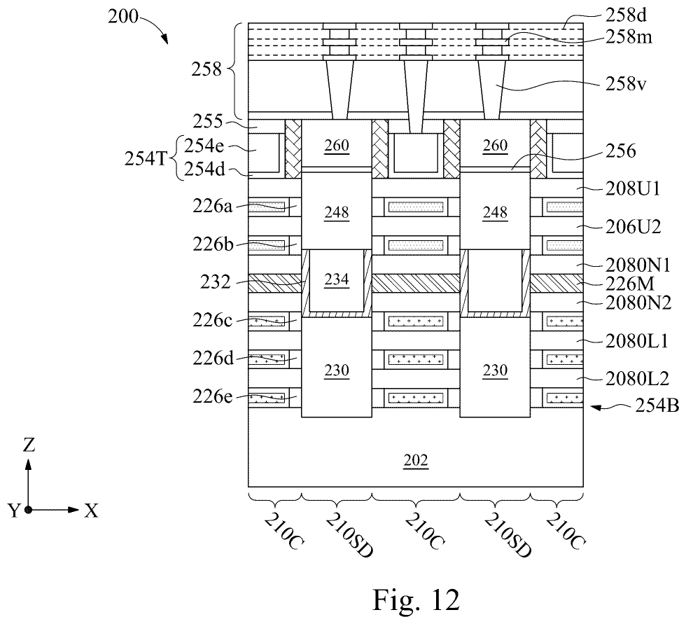

Referring to FIGS. 2 and 12, method 100 includes a block 122 where further processes are performed to complete the fabrication of the semiconductor device 200. Such further processes may include forming a dielectric capping layer 255 over the top gate structure 254T. Such further processes may also include forming a silicide layer 256 over the top source/drain features 248 and forming a multi-layer interconnect (MLI) structure 258 over the intermediate structure 200. The MLI 258 may include various interconnect features, such as vias 258v and conductive lines 258m, disposed in dielectric layers 258d, such as etch-stop layers and ILD layers. In some embodiments, the vias are vertical interconnect features configured to interconnect device-level contacts, such as source/drain contacts 260 formed over the top source/drain features 248. Other processes may be further performed.

Although not intended to be limiting, one or more embodiments of the present disclosure provide many benefits to a semiconductor device and the formation thereof. For example, the present disclosure provides a C-FET device having a top multi-gate device and a bottom multi-gate device. An aluminum diffusion barrier layer is formed between two p-type work function layers to reduce aluminum from being diffused into the lower one of the p-type work function layers, thereby reducing threshold voltage variation of the bottom multi-gate device.

The present disclosure provides for many different embodiments. Semiconductor structures and methods of fabrication thereof are disclosed herein. In one exemplary aspect, the present disclosure is directed to a method. The method includes forming a first semiconductor layer stack having a first upper semiconductor layer over a first lower semiconductor layer and a second semiconductor layer stack having a second upper semiconductor layer over a second lower semiconductor layer, forming a high-k dielectric layer over the first upper semiconductor layer, the second upper semiconductor layer, the first lower semiconductor layer, and the second lower semiconductor layer, forming a p-type work function structure over the high-k dielectric layer, the first upper semiconductor layer, and the first lower semiconductor layer, wherein the p-type work function structure comprises a first p-type work function layer, a metal layer on the first p-type work function layer, and a second p-type work function layer on the metal layer, and forming an n-type work function layer over the high-k dielectric layer, the second upper semiconductor layer, the second lower semiconductor layer, and the p-type work function structure.

In some embodiments, the first p-type work function layer and the second p-type work function layer may include titanium nitride. In some embodiments, the n-type work function layer may include an aluminum-containing material. In some embodiments, an aluminum concentration of the first p-type work function layer is less than an aluminum concentration of the second p-type work function layer comprise titanium nitride. In some embodiments, the first p-type work function layer, the second p-type work function layer, and the metal layer may include a same metal element. In some embodiments, the metal layer may include titanium. In some embodiments, a ratio of a thickness of the metal layer to a total thickness of the first p-type work function layer and the second p-type work function layer is between about 0.1 and about 0.2. In some embodiments, the method may also include forming a first source/drain feature coupled to the first upper semiconductor layer and the first lower semiconductor layer, forming a second source/drain feature coupled to the second upper semiconductor layer and the second lower semiconductor layer, and forming an isolation structure between the first source/drain feature and the second source/drain feature. In some embodiments, the p-type work function structure may include a first oxide layer disposed between the metal layer and the first p-type work function layer and a second oxide layer disposed between the metal layer and the second p-type work function layer.

In another exemplary aspect, the present disclosure is directed to a method. The method includes forming a plurality of nanostructures over a substrate, forming a first source/drain feature coupled to a bottommost nanostructure of the plurality of nanostructures, forming a second source/drain feature coupled to a topmost nanostructure of the plurality of nanostructures, forming a first gate structure wrapping around the bottommost nanostructure, and forming a second gate structure wrapping around the topmost nanostructure, where the second gate structure comprises an aluminum-containing n-type work function layer, the first gate structure comprises a first p-type work function layer, a second p-type work function layer, and a diffusion barrier layer disposed between the first p-type work function layer and the second p-type work function layer, wherein an aluminum concentration of the first p-type work function layer is less than an aluminum concentration of the second p-type work function layer.

In some embodiments, the first p-type work function layer and the second p-type work function layer may include titanium nitride. In some embodiments, the diffusion barrier layer may include a titanium layer. In some embodiments, a thickness of the diffusion barrier layer is between about 0.1 nm and about 0.3 nm. In some embodiments, a total thickness of the first p-type work function layer and the second p-type work function layer is between about 1 nm and about 3 nm. In some embodiments, a thickness of the second p-type work function layer is less than a thickness of the first p-type work function layer. In some embodiments, the forming of the first gate structure may include performing an in-situ deposition process to form the first p-type work function layer, the second p-type work function layer, and the diffusion barrier layer.

In yet another exemplary aspect, the present disclosure is directed to a semiconductor structure. The semiconductor structure includes a substrate, a lower source/drain feature disposed over the substrate, a first plurality of nanostructures coupled to the lower source/drain feature, a first gate structure wrapping around each of the first plurality of nanostructures, an upper source/drain feature over the lower source/drain feature, a second plurality of nanostructures coupled to the upper source/drain feature, and a second gate structure wrapping around each of the second plurality of nanostructures, where the first gate structure comprises a gate dielectric layer, a first p-type work function layer over the gate dielectric layer, a metal layer over the first p-type work function layer, and a second p-type work function layer over the metal layer.

In some embodiments, the second gate structure may include an n-type work function layer, and in a cross-section that extends through the first plurality of nanostructures and the second plurality of nanostructures without extending through the lower and upper source/drain features, a portion of the n-type work function layer is on the metal layer. In some embodiments, in another cross-section that extends through the first and second plurality of nanostructures and the lower and upper source/drain features, the first gate structure and the second gate structure are vertically spaced apart from one another by a dielectric layer. In some embodiments, a thickness of the second p-type work function layer is less than a thickness of the first p-type work function layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor layer stack having a first upper semiconductor layer over a first lower semiconductor layer and a second semiconductor layer stack having a second upper semiconductor layer over a second lower semiconductor layer;
forming a high-k dielectric layer over the first upper semiconductor layer, the second upper semiconductor layer, the first lower semiconductor layer, and the second lower semiconductor layer;
forming a p-type work function structure over the high-k dielectric layer, the first upper semiconductor layer, and the first lower semiconductor layer, wherein the p-type work function structure comprises a first p-type work function layer, a metal layer on the first p-type work function layer, and a second p-type work function layer on the metal layer; and
forming an n-type work function layer over the high-k dielectric layer, the second upper semiconductor layer, the second lower semiconductor layer, and the p-type work function structure.

2. The method of claim 1, wherein the first p-type work function layer and the second p-type work function layer comprise titanium nitride.

3. The method of claim 1, wherein the n-type work function layer comprises an aluminum-containing material.

4. The method of claim 1, wherein an aluminum concentration of the first p-type work function layer is less than an aluminum concentration of the second p-type work function layer comprise titanium nitride.

5. The method of claim 1, wherein the first p-type work function layer, the second p-type work function layer, and the metal layer comprise a same metal element.

6. The method of claim 1, wherein the metal layer comprises titanium.

7. The method of claim 1, wherein a ratio of a thickness of the metal layer to a total thickness of the first p-type work function layer and the second p-type work function layer is between about 0.1 and about 0.2.

8. The method of claim 1, further comprising:
forming a first source/drain feature coupled to the first upper semiconductor layer and the first lower semiconductor layer;
forming a second source/drain feature coupled to the second upper semiconductor layer and the second lower semiconductor layer; and
forming an isolation structure between the first source/drain feature and the second source/drain feature.

9. The method of claim 1, wherein the p-type work function structure further comprises a first oxide layer disposed between the metal layer and the first p-type work function layer and a second oxide layer disposed between the metal layer and the second p-type work function layer.

10. A method, comprising:
forming a plurality of nanostructures over a substrate;
forming a first source/drain feature coupled to a bottommost nanostructure of the plurality of nanostructures;
forming a second source/drain feature coupled to a topmost nanostructure of the plurality of nanostructures;
forming a first gate structure wrapping around the bottommost nanostructure; and
forming a second gate structure wrapping around the topmost nanostructure,
wherein the second gate structure comprises an aluminum-containing n-type work function layer, the first gate structure comprises a first p-type work function layer, a second p-type work function layer, and a diffusion barrier layer disposed between the first p-type work function layer and the second p-type work function layer, wherein an aluminum concentration of the first p-type work function layer is less than an aluminum concentration of the second p-type work function layer.

11. The method of claim 10, wherein the first p-type work function layer and the second p-type work function layer comprise titanium nitride.

12. The method of claim 10, wherein the diffusion barrier layer comprises a titanium layer.

13. The method of claim 10, wherein a thickness of the diffusion barrier layer is between about 0.1 nm and about 0.3 nm.

14. The method of claim 10, wherein a total thickness of the first p-type work function layer and the second p-type work function layer is between about 1 nm and about 3 nm.

15. The method of claim 10, wherein a thickness of the second p-type work function layer is less than a thickness of the first p-type work function layer.

16. The method of claim 10, wherein the forming of the first gate structure comprises performing an in-situ deposition process to form the first p-type work function layer, the second p-type work function layer, and the diffusion barrier layer.

17. A semiconductor device, comprising:
a substrate;
a lower source/drain feature disposed over the substrate;
a first plurality of nanostructures coupled to the lower source/drain feature;
a first gate structure wrapping around each of the first plurality of nanostructures;
an upper source/drain feature over the lower source/drain feature;
a second plurality of nanostructures coupled to the upper source/drain feature; and
a second gate structure wrapping around each of the second plurality of nanostructures,
wherein the first gate structure comprises a gate dielectric layer, a first p-type work function layer over the gate dielectric layer, a metal layer over the first p-type work function layer, and a second p-type work function layer over the metal layer.

18. The semiconductor device of claim 17, wherein the second gate structure comprises an n-type work function layer, and in a cross-section that extends through the first plurality of nanostructures and the second plurality of nanostructures without extending through the lower and upper source/drain features, a portion of the n-type work function layer is on the metal layer.

19. The semiconductor device of claim 18, wherein in another cross-section that extends through the first and second plurality of nanostructures and the lower and upper source/drain features, the first gate structure and the second gate structure are vertically spaced apart from one another by a dielectric layer.

20. The semiconductor device of claim 19, wherein a thickness of the second p-type work function layer is less than a thickness of the first p-type work function layer.
